(19) United States
(12) Patent Application Publication
(10) Pub. No.: US 2013/0009661 A1
(43) Pub. Date: Jan. 10, 2013

(54) TESTING CIRCUIT FOR PSVA AND ARRAY

(75) Inventor: Cheng-hung Chen, Guangdong (CN)

(73) Assignee: SHENZHEN CHINA STAR OPTOELECTRONICS TECHNOLOGY CO., LTD., Shenzhen (CN)

(21) Appl. No.: 13/376,590

(22) PCT Filed: Aug. 26, 2011
(86) PCT No.: PCT/CN11/78957

§ 371 Date: Dec. 7, 2011

(30) Foreign Application Priority Data
Jul. 4, 2011 (CN) 201110185553.5

(51) Int. Cl. G01R 31/26

(52) U.S. Cl. 324/760.02

(57) ABSTRACT

The present invention relates to a field of LCD technology, especially to a testing circuit for PSVA and array. The testing circuit for PSVA and array has gate signal lines, data signal lines, a first solder pad and thin-film transistors. Extension lines of the gate signal lines and the data signal lines are each connected to a drain of a corresponding one of the thin-film transistors. Sources of the thin-film transistors corresponding to the data signal lines are connected to each other and connected to the first solder pad. Gates of the thin-film transistors corresponding to the data signal lines are connected to a transfer structure on a substrate. Sources and gates of the thin-film transistors corresponding to the gate signal lines are connected to each other and connected to the transfer structure. Comparing with conventional testing circuit for PSVA and array, techniques provided by the present invention effectively reduces the number of solder pads at glass edges and simplifies complexity of overall circuit.

### FIELD OF THE INVENTION

The present invention relates to a field of technology of LCD, especially to a testing circuit for PSVA and array.

### BACKGROUND OF THE INVENTION

In the present PSVA (Polymer Stabilized Vertical Alignment) manufacturing process, in order to execute circuit test during the array manufacturing process, generally a so-called shorting bar will be used to connect all of the gate lines and data lines to signal G1, G2, . . . , Gn and D1, D2, . . . , Dm, specifically as shown in FIG. 1, wherein the value of n and m must be designed to be larger or equal to 2 such that a condition that adjacent data lines or adjacent gate lines are short-circuited with each other can be checked during test. Hence each chip may have corresponding G1, G2, . . . , Gn and D1, D2, . . . , Dm, and a plurality of common signal pads C1, C2, . . . , Cx (collectively called “com”) as the input points for applied signal when executing array testing. In order to let those lines in PSVA manufacturing process also be able to be used by applied voltages, a traditional way is to let G1, G2, . . . , Gn and D1, D2, . . . , Dm, and the common signal pads C1, C2, . . . , Cx to which each chip corresponds on a glass be connected to the pads on edges of the glass, inner edges of the glass will be removed before a subsequent cell process of the PSVA manufacturing process such that the pads will be exposed and can be successfully applied with voltages. However, if the glass has a larger amount of chips, it will cause too much pads to be set on the edges of the glass, which will increase the number of probes for applying voltages in PSVA manufacturing process and the complexity of the entire peripheral circuit.

Hence, it is necessary to provide a testing circuit for PSVA and array to overcome the problems existing in the conventional technology.

### SUMMARY OF THE INVENTION

An object of the invention is to provide a testing circuit for PSVA and array to solve the problems about conventional array testing circuits being requiring a large number of probes and having complicated peripheral circuit configuration.

The present invention is implemented as follows:

A testing circuit for PSVA and array comprising gate signal lines and data signal lines, a first solder pad, a second solder pad and a plurality of thin-film transistors; extension lines of the gate signal lines and the data signal lines are each connected to a drain of a corresponding one of the thin-film transistors; sources of the thin-film transistors corresponding to the data signal lines are connected to each other and connected to the first solder pad; gates of the thin-film transistors corresponding to the data signal lines are connected to a transfer structure on a substrate; sources and gates of the thin-film transistors corresponding to the gate signal lines are connected to each other and connected to the transfer structure on the substrate; the second solder pad is disposed on a side of the first solder pad and connected to the transfer structure on the substrate, and the first solder pad and the second solder pad are independent to each other.

In a preferred embodiment of the present invention, further comprises common-signal-line solder pads, and the common-signal-line solder pads are connected to each other and connected to the transfer structure on the substrate.

In a preferred embodiment of the present invention, the transfer structure on the substrate is coated with electric conductive materials and is connected to an electric conductive layer on an upper board of the substrate.

In a preferred embodiment of the present invention, the number of the gate signal lines and the number of the data signal lines each is at least one.

The present invention further provides another testing circuit for PSVA and array having gate signal lines and data signal lines, a first solder pad and a plurality of thin-film transistors, and extension lines of the gate signal lines and the data signal lines are each connected to a drain of a corresponding one of the thin-film transistors; sources of the thin-film transistors corresponding to the data signal lines are connected to each other and connected to the first solder pad; gates of the thin-film transistors corresponding to the data signal lines are connected to a transfer structure on a substrate; sources and gates of the thin-film transistors corresponding to the gate signal lines are connected to each other and connected to the transfer structure on the substrate.

In a preferred embodiment of the present invention, further comprises a second solder pad, and the second solder pad is disposed on a side of the first solder pad and connected to the transfer structure on the substrate.

In a preferred embodiment of the present invention, comprises common-signal-line solder pads, and the common-signal-line solder pads are connected to each other and connected to the transfer structure on the substrate.

In a preferred embodiment of the present invention, the common-signal-line solder pads are connected to the first solder pads.

In a preferred embodiment of the present invention, the transfer structure on the substrate is coated with electric conductive materials and is connected to an electric conductive layer on an upper board of the substrate.

In a preferred embodiment of the present invention, the number of the gate signal lines and the number of the data signal lines each is at least one.

The present invention further provides another testing circuit for PSVA and array having gate signal lines and data signal lines, a first solder pad and a plurality of thin-film transistors, and extension lines of the gate signal lines and the data signal lines are each connected to a drain of a corresponding one of the thin-film transistors; gates of the thin-film transistors respectively corresponding to the gate signal lines and the data signal lines are respectively connected a transfer structure on a substrate; sources of the thin-film transistors corresponding to the data signal lines are connected to each other and connected to the first solder pad; sources of the thin-film transistors corresponding to the gate signal lines are connected to each other and connected to the first solder pad.

In a preferred embodiment of the present invention, further comprises a second solder pad and a plurality of common-signal-line solder pads, the second solder pad is connected to the transfer structure on the substrate, and the common-signal-line solder pads are connected to each other and connected to the transfer structure on the substrate.

In a preferred embodiment of the present invention, the transfer structure on the substrate is coated with electric conductive material and connected to an electric conductive layer of an upper board of the substrate.

In a preferred embodiment of the present invention, the number of the gate signal lines and the number of the data signal lines each is at least one.

Comparing with the conventional testing circuit for PSVA and array, the techniques provided by the present invention make extension lines of the gate signal lines and the data signal lines to be connected to a drain of a corresponding one of the thin-film transistors, sources of the thin-film transistors corresponding to the data signal lines to be connected to each other and connected to the first solder pad, gates of the thin-film transistors corresponding to the data signal lines to be connected to a transfer structure on a substrate, sources and gates of the thin-film transistors corresponding to the gate signal lines to be connected to each other and connected to the transfer structure, and the transfer structure on the substrate to be coated with electric conductive materials so as to connect to an electric conductive layer on an upper board of the substrate, and thereby effectively reduces the number of solder pads at glass edges and simplifies complexity of overall circuit.

In order to make the contents of the present invention to be easily understood, below, the preferred embodiments of the present invention are described in detail in cooperation with accompanying drawings as follows:

### DESCRIPTION OF THE DRAWINGS

FIG. 1 is a schematic diagram of a configuration of a testing circuit for PSVA and array in accordance with the prior art;

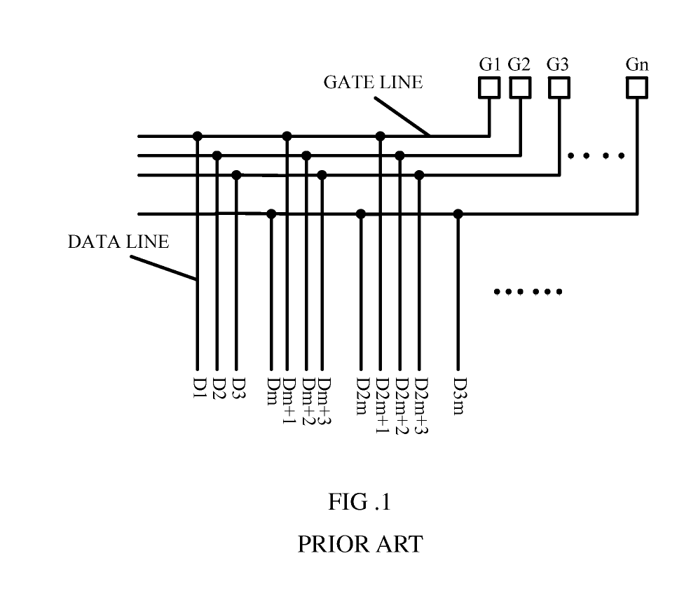

FIG. 2 is a schematic diagram of a configuration of a testing circuit for PSVA and array of a first preferred embodiment in accordance with the present invention;

FIG. 3 is a schematic diagram of a configuration of a testing circuit for PSVA and array of a second preferred embodiment in accordance with the present invention; and

FIG. 4 is a schematic diagram of a configuration of a testing circuit for PSVA and array of a third preferred embodiment in accordance with the present invention.

### DETAILED DESCRIPTION OF THE PREFERRED EMBODIMENTS

The foregoing objects, features and advantages adopted by the present invention can be best understood by referring to the following detailed description of the preferred embodiments and the accompanying drawings. Furthermore, the directional terms described in the present invention, such as upper, lower, front, rear, left, right, inner, outer, side and etc., are only directions referring to the accompanying drawings, so that the used directional terms are used to describe and understand the present invention, but the present invention is not limited thereto.

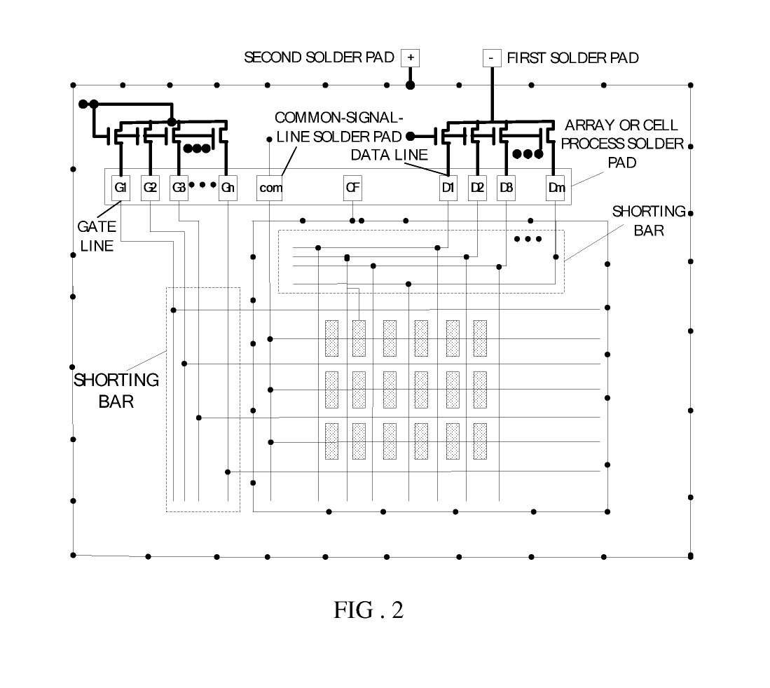

With reference to FIG. 2, a schematic diagram of a configuration of a testing circuit for PSVA and array of a first preferred embodiment in accordance with the present invention, as shown in FIG. 2, each of extension lines of gate lines G1, G2, . . . , Gn and data lines D1, D2, . . . , Dm is connected to a drain of a corresponding one of thin-film transistors. Sources of the thin-film transistors corresponding to the data lines D1, D2, . . . , Dm are connected to each other and extended to a first solder pad (Pad1) at an edge of a glass via an signal line. Gates of the thin-film transistors are connected to a transfer structure on a substrate; sources and gates of the thin-film transistors corresponding to the gate lines G1, G2, . . . , Gn are connected to each other and connected to the transfer structure on the substrate together, a second solder pad (Pad2) is directly connected to the transfer structure on the substrate; common-signal-line solder pads C1, C2, . . . , Cx (collectively called “com”) are connected to each other and connected to the transfer structure on the substrate; wherein, the transfer structure is coated with electric conductive material during a cell assembling process to connect to an electric conductive layer of an upper board.

Therefore while executing an array testing, since there is no opposite side glass, gates of all TFTs are in floating electric potential, the TFTs are switched off, high resistance exist between the sources and the drains, and pads that all of the gate lines G1, G2, . . . , Gn and data lines D1, D2, . . . , Dm corresponds to are at an independent status, therefore different pads can be applied with different signals to test the array. During a process of assembling an upper and an lower glasses of cell, since the electric conductive materials in the transfer is electrically conducted to the electric conductive layer of the upper board, therefore all the lines connected to the transfer are receiving a signal identical to the signal applied to Pad2, while Pad2 will be applied with a higher electric potential signal comparing to Pad1 during the PSVA manufacturing process, and this may cause the electric conductive layer of all the transfer and the opposite side glass to be at high electric potential, and the gates of the thin-film transistors will all be at high electric potential, therefore the resistance between the sources and the drains is lowered and can be taken as being at a conductive status, signals applied to the sources of the transistors can thereby enter all of the lines G1, G2, . . . , Gn and D1, D2, . . . , Dm, and smoothly provide a required electric potential for pixel curing.

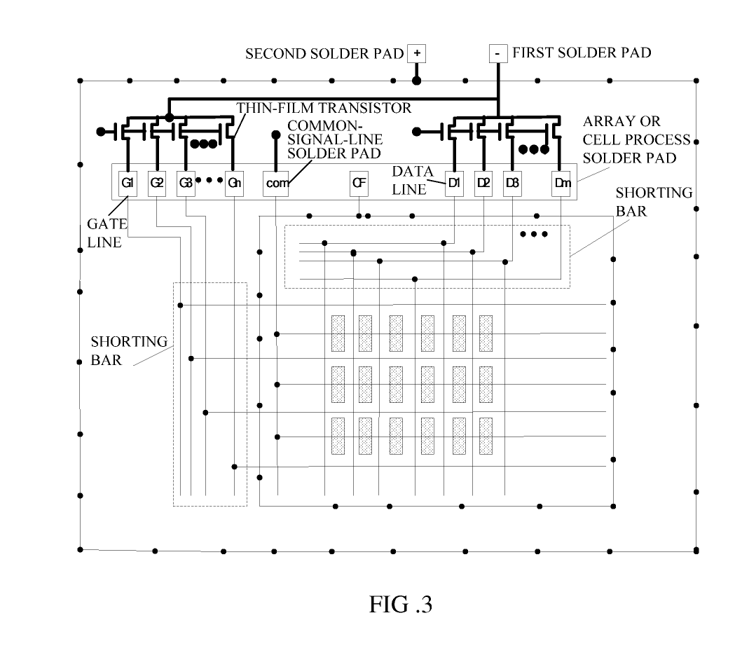

As shown in FIG. 3, a schematic diagram of a configuration of a testing circuit for PSVA and array of a second preferred embodiment provided by the present invention, in FIG. 3, each of extension lines of gate lines G1, G2, . . . , Gn and data lines D1, D2, . . . , Dm is connected to a drain of a corresponding one of thin-film transistors. Gates of the thin-film transistors respectively corresponding to gate lines G1, G2, . . . , Gn and data lines D1, D2, . . . , Dm are each connected to the transfer structure on the substrate, sources of the thin-film transistors corresponding to the data lines D1, D2, . . . , Dm are connected to each other and extended to a first solder pad (Pad1) at an edge of a glass via an signal line; sources of the thin-film transistors corresponding to the gate lines G1, G2, . . . , Gn are connected to each other and use a signal line to connect to a signal line which connects the sources of the thin-film transistors corresponding to D1, D2, . . . , Dm to the first solder pad and extends to the first solder pad (Pad1) at the edge of the glass. A second solder pad (Pad2) is directly connected to the transfer structure on the substrate. Common-signal-line solder pads C1, C2, . . . , Cx are connected to each other and connected to the transfer structure on the substrate together, wherein the transfer structure is coated with electric conductive materials to connect to an electric conductive layer of an upper board during the cell assembling process.

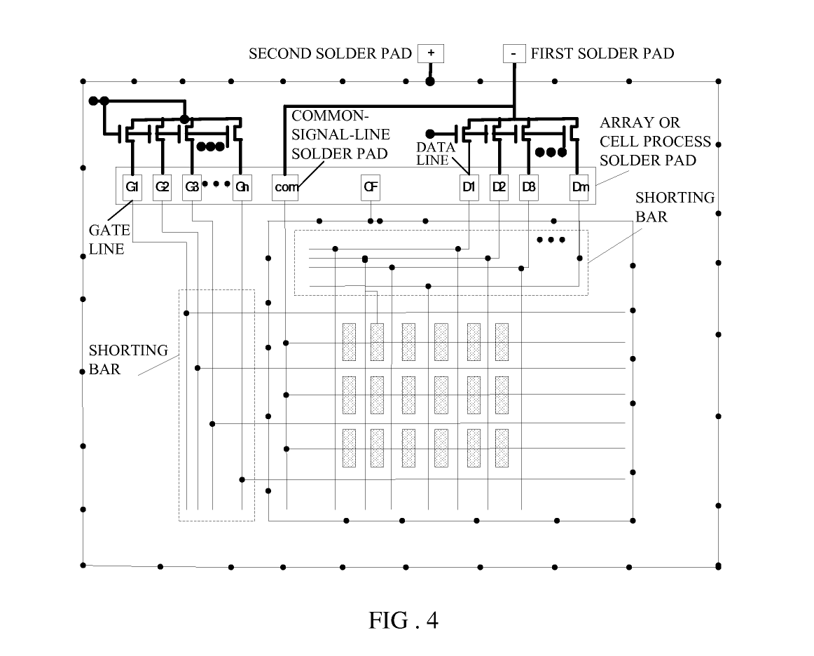

As shown in FIG. 4, a schematic diagram of a configuration of a testing circuit for PSVA and array of a third preferred embodiment provided by the present invention, in FIG. 4, each of extension lines of gate lines G1, G2, . . . , Gn and data lines D1, D2, . . . , Dm is connected to a drain of a corresponding one of thin-film transistors. Sources of the thin-film transistors corresponding to the data lines D1, D2, . . . , Dm are connected together and extend to a first solder pad (Pad1) at an edge of a glass. Gates of the thin-film transistors are connected to a transfer structure on a substrate, the sources and the gates of the thin-film transistors corresponding to the gate lines G1, G2, . . . , Gn are connected to each other and connected to the transfer structure on the substrate together. A second solder pad (Pad2) at the edge of the glass is directly connected to the transfer structure on the substrate. Common-signal-line solder pads C1, C2, . . . , Cx(collectively called “Cx”) use a signal line to connect to a signal line which connects the sources of the thin-film transistors corresponding to D1, D2, . . . , Dm to the first solder pad and extend to the first solder pad (Pad1) at the edge of the glass, wherein, the transfer structure is coated with electric conductive materials to connect to an electric conductive layer of an upper board during cell assembling process.

The present invention has been described with a preferred embodiment thereof and it is understood that many changes and modifications to the described embodiment can be carried out without departing from the scope and the spirit of the invention that is intended to be limited only by the appended claims.

1. A testing circuit for PSVA and array comprising gate signal lines and data signal lines, characterized in that: the testing circuit further comprises a first solder pad, a second solder pad and a plurality of thin-film transistors, wherein extension lines of the gate signal lines and the data signal lines are each connected to a drain of a corresponding one of the thin-film transistors; sources of the thin-film transistors corresponding to the data signal lines are connected to each other and connected to the first solder pad; gates of the thin-film transistors corresponding to the data signal lines are connected to a transfer structure on a substrate; sources and gates of the thin-film transistors corresponding to the gate signal lines are connected to each other and connected to the transfer structure on the substrate; the second solder pad is disposed on a side of the first solder pad and connected to the transfer structure on the substrate, and the first solder pad and the second solder pad are independent to each other.

2. The testing circuit for PSVA and array as claimed in claim 1, characterized in that: the testing circuit for PSVA and array further comprises common-signal-line solder pads, and the common-signal-line solder pads are connected to each other and connected to the transfer structure on the substrate.

3. The testing circuit for PSVA and array as claimed in claim 2, characterized in that: the transfer structure on the substrate is coated with electric conductive materials and is connected to an electric conductive layer on an upper board of the substrate.

4. The testing circuit for PSVA and array as claimed in claim 2, characterized in that: the number of the gate signal lines and the number of the data signal lines each is at least one.

5. A testing circuit for PSVA and array comprising gate signal lines and data signal lines, characterized in that: the testing circuit further comprises a first solder pad and a plurality of thin-film transistors, wherein extension lines of the gate signal lines and the data signal lines are each connected to a drain of a corresponding one of the thin-film transistors; sources of the thin-film transistors corresponding to the data signal lines are connected to each other and connected to the first solder pad; gates of the thin-film transistors corresponding to the data signal lines are connected to a transfer structure on a substrate; sources and gates of the thin-film transistors corresponding to the gate signal lines are connected to each other and connected to the transfer structure on the substrate.

6. The testing circuit for PSVA and array as claimed in claim 5, characterized in that: further comprises a second solder pad, and the second solder pad is disposed on a side of the first solder pad and connected to the transfer structure on the substrate.

7. The testing circuit for PSVA and array as claimed in claim 5, characterized in that: the testing circuit for PSVA and array further comprises common-signal-line solder pads, and the common-signal-line solder pads are connected to each other and connected to the transfer structure on the substrate.

8. The testing circuit for PSVA and array as claimed in claim 5, characterized in that: the common-signal-line solder pads are connected to the first solder pads.

9. The testing circuit for PSVA and array as claimed in claim 5, characterized in that: the transfer structure on the substrate is coated with electric conductive materials and is connected to an electric conductive layer on an upper board of the substrate.

10. The testing circuit for PSVA and array as claimed in claim 5, characterized in that: the number of the gate signal lines and the number of the data signal lines each is at least one.

11. A testing circuit for PSVA and array comprising gate signal lines and data signal lines, characterized in that: the testing circuit further comprises a first solder pad and a plurality of thin-film transistors, wherein extension lines of the gate signal lines and the data signal lines are each connected to a drain of a corresponding one of the thin-film transistors; gates of the thin-film transistors respectively corresponding to the gate signal lines and the data signal lines are respectively connected a transfer structure on a substrate; sources of the thin-film transistors corresponding to the data signal lines are connected to each other and connected to the first solder pad; sources of the thin-film transistors corresponding to the gate signal lines are connected to each other and connected to the first solder pad.

12. The testing circuit for PSVA and array as claimed in claim 11, characterized in that: the testing circuit for PSVA and array further comprises a second solder pad and a plurality of common-signal-line solder pads, the second solder pad is connected to the transfer structure on the substrate, and the common-signal-line solder pads are connected to each other and connected to the transfer structure on the substrate.

13. The testing circuit for PSVA and array as claimed in claim 11, characterized in that: the transfer structure on the substrate is coated with electric conductive material and connected to an electric conductive layer of an upper board of the substrate.

14. The testing circuit for PSVA and array as claimed in claim 11, characterized in that: the number of the gate signal lines and the number of the data signal lines each is at least one.

15. The testing circuit for PSVA and array as claimed in claim 6, characterized in that: the testing circuit for PSVA and array further comprises common-signal-line solder pads, and the common-signal-line solder pads are connected to each other and connected to the transfer structure on the substrate.

16. The testing circuit for PSVA and array as claimed in claim 6, characterized in that: the common-signal-line solder pads are connected to the first solder pads.

17. The testing circuit for PSVA and array as claimed in claim 6, characterized in that: the transfer structure on the substrate is coated with electric conductive materials and is connected to an electric conductive layer on an upper board of the substrate.

18. The testing circuit for PSVA and array as claimed in claim 12, characterized in that: the transfer structure on the substrate is coated with electric conductive material and connected to an electric conductive layer of an upper board of the substrate.

19. The testing circuit for PSVA and array as claimed in claim 12, characterized in that: the number of the gate signal lines and the number of the data signal lines each is at least one.
